(19) United States
(12) Patent Application Publication
(10) Pub. No.: US 2011/0006799 A1
(43) Pub. Date: Jan. 13, 2011

(54) METHOD FOR MANUFACTURING PROBE SUPPORTING PLATE, COMPUTER STORAGE MEDIUM AND PROBE SUPPORTING PLATE

(75) Inventors: Jun Mochizuki, Nirasaki-shi (JP); Shinichiro Takase, Nirasaki-shi (JP)

Correspondence Address: CANTOR COLBURN LLP, 20 Church Street, 22nd Floor, Hartford, CT, 06103, US

(73) Assignee: TOKYO ELECTRON LIMITED, Tokyo (JP)

(21) Appl. No.: 12/865,476

(22) PCT Filed: Feb. 17, 2009
(86) PCT No.: PCT/JP2009/052666

§ 371 Date: Jul. 30, 2010

(30) Foreign Application Priority Data
Feb. 21, 2008 (JP) 2008-039963

(51) Int. Cl. G01R 31/00; C23F 1/00; C23F 1/08; B32B 37/16

(52) U.S. Cl. 324/756.07; 216/37; 156/345.24; 156/60

(57) ABSTRACT

A prescribed pattern is formed on a thin metal plate by photolithography. The thin metal plate is etched by using the pattern as a mask to form a plurality of through-holes having diameters greater than diameters of probes, in the thin metal plate. The etching is performed on a plurality of the thin metal plates. After the pattern is removed, the plurality of thin metal plates are laminated by conforming the through-holes of each of the thin metal plates to guide pins of a guide. The laminated plurality of thin metal plates are bonded by diffusion bonding. An insulating film is formed on surfaces of the thin metal plates and an inner surface of each of the through-holes. A film thickness of the insulating film is adjusted so that inner diameters of the through-holes whereupon the insulating film is formed match with the diameters of the probes.

### TECHNICAL FIELD

The present invention relates to a method for manufacturing a probe supporting plate which supports a plurality of probes for inspecting electrical characteristics of an object to be inspected, a computer storage medium which stores a program for executing the method, and a probe supporting plate.

### BACKGROUND ART

Inspection of electrical characteristics of an electronic circuit, such as an IC, LSI, or the like, formed on, for example, a semiconductor wafer (hereinafter, referred to as a wafer) is performed by bringing a plurality of probes into contact with electrodes of the electronic circuit and making each of the probes apply an electrical signal for inspection to a corresponding electrode. The plurality of probes are formed of a metal material, for example, nickel, cobalt, or the like, and are inserted into and supported by a probe supporting plate. A plurality of through-holes into which the plurality of probes are to be inserted are formed in the probe supporting plate. In order to appropriately perform the inspection, the probe supporting plate which supports the probes is formed of an insulating material that does not affect the electrical signals of the probes, for example, ceramic or the like.

In the formation of the plurality of through-holes in the probe supporting plate formed of ceramic or the like, all of the through-holes are formed by mechanical machining in a conventional method (Patent Document 1).

### PRIOR ART DOCUMENT

### Patent Document

(Patent Document 1) Japanese Laid-Open Patent Publication No. 2007-33438

### DISCLOSURE OF THE INVENTION

### Technical Problem

However, recently, as a pattern of an electronic circuit becomes finer, electrodes become finer, and distances between the electrodes become smaller. Therefore probes which are to be brought into contact with the electrodes are being required to become finer and have a narrower pitch. That is, a plurality of fine through-holes need to be formed in a probe supporting plate. Accordingly, if all of the through-holes are formed by mechanical machining as in a conventional method, it takes a lot of time to manufacture the probe supporting plate. Also, since the number of processes for manufacturing the probe supporting plate is increased, manufacturing costs are also increased.

The present invention is proposed considering the aforementioned state of art. According to the invention, it may be obtained to manufacture a probe supporting plate in a short time at low costs.

### Technical Solution

In the present invention, there is provided a method for manufacturing a probe supporting plate which holds a plurality of probes for inspecting electrical characteristics of an object to be inspected, the method including: an etching process of etching a metal plate to form a plurality of through-holes into which the probes are to be inserted, in the metal plate; and a film forming process of forming an insulating film on each of inner surfaces of the through-holes.

According to the present invention, since the metal plate is etched to form the plurality of through-holes into which the probes are to be inserted, the plurality of through-holes may be simultaneously formed in one metal plate through one etching process. Accordingly, since there is no need to form all of the through-holes through mechanical machining as in a conventional method, the probe supporting plate may be manufactured in an extremely short time. Also, since the number of manufacturing processes is reduced, the probe supporting plate may be manufactured at low costs. In addition, since the insulating film is formed on each of the through-holes, the metal plate and the probes are insulated from each other, and thus when electrical characteristics of an object to be inspected are inspected, the metal plate does not affect electrical signals of the probes. Also, a mask used to etch the metal plate may be formed on the metal plate by performing, for example, photolithography, on the metal plate.

### ADVANTAGEOUS EFFECTS

According to the present invention, a probe supporting plate may be manufactured in an extremely shorter time at lower costs than that manufactured in a conventional method.

### BRIEF DESCRIPTION OF THE DRAWINGS

FIG. 1 is a side view schematically showing a configuration of a probe device to which a probe supporting plate according to an embodiment of the present invention is applied.

FIG. 2 is a longitudinal-sectional view of the probe supporting plate according to the embodiment of the present invention.

FIG. 3 is a cross-sectional view of the probe supporting plate according to the embodiment of the present invention.

FIG. 4 is an explanatory view showing processes for manufacturing the probe supporting plate according to the embodiment of the present invention, wherein (a) shows a state where a prescribed pattern is formed on a thin metal plate, (b) shows a state where the thin metal plate is etched to form a plurality of through-holes, (c) shows a state where a plurality of the thin metal plates are laminated, (d) shows a state where the plurality of thin metal plates are bonded, and (e) shows a state where an insulating film is formed on surfaces of the thin metal plates and an inner surface of each of the through-holes.

FIG. 5 is a longitudinal-sectional view of a probe supporting plate according to another embodiment of the present invention.

FIG. 6 is a longitudinal-sectional view of a probe supporting plate according to another embodiment of the present invention.

FIG. 7 is a longitudinal-sectional view of a probe supporting plate according to another embodiment of the present invention.

### DESCRIPTION OF REFERENCE NUMERALS

10: probe
11: probe supporting plate
20: thin metal plate
21: through-hole
22: insulating film
30: pattern
31: guide
40: hole
W: wafer

### BEST MODE FOR CARRYING OUT THE INVENTION

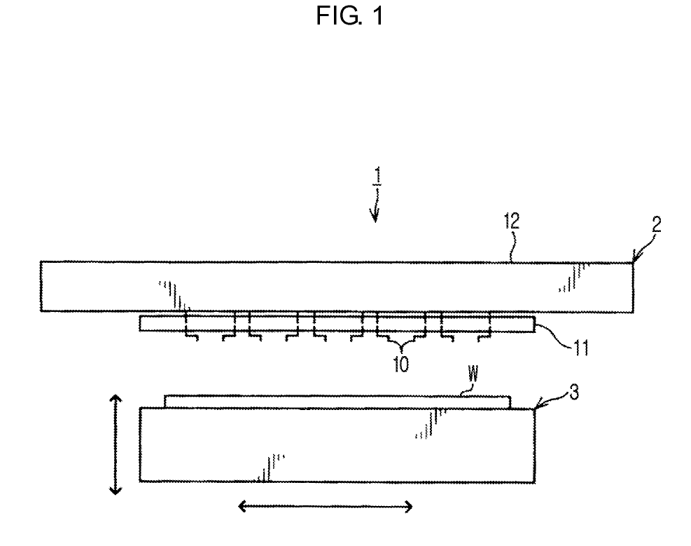

Herein below, embodiments of the present invention will be explained. FIG. 1 is an explanatory side view schematically showing a configuration of a probe device 1 to which a probe supporting plate according to an embodiment of the present invention is applied.

The probe device 1 includes a probe card 2, and a holding stage 3 on which a wafer W as an object to be inspected is placed.

The probe card 2 includes a probe supporting plate 11 which holds a plurality of probes 10 contacting electrodes of the wafer W, and a printed wiring board 12 which transmits and receives an electrical signal to and from the probes 10 through a main body of the probe supporting plate 11. The probe supporting plate 11 is formed to face the holding stage 3, and the probes 10 supported by the probe supporting plate 11 are formed at positions corresponding to the electrodes of the wafer W. The printed wiring board 12 is disposed over a top surface of the probe supporting plate 11.

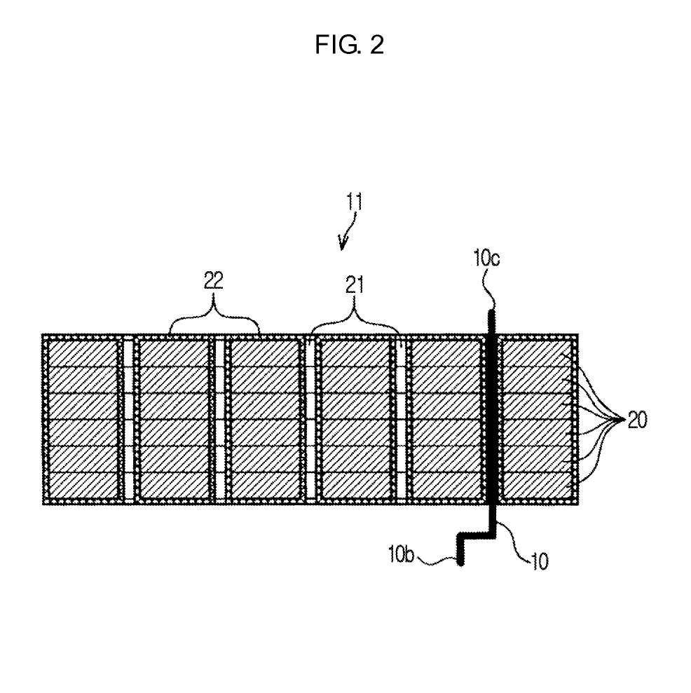

The probes 10 are formed of a conductive metal material, for example, nickel, cobalt, or the like. As shown in FIG. 2, the probes 10 are supported by the probe supporting plate 11 by passing through the probe supporting plate 11, for example, in a thickness direction of the probe supporting plate 11. Front end portions 10b of the probes 10 protrude from a bottom surface of the probe supporting plate 11, and base end portions 10c of the probes 10 are connected to (not shown) contact terminals of the printed wiring board 12.

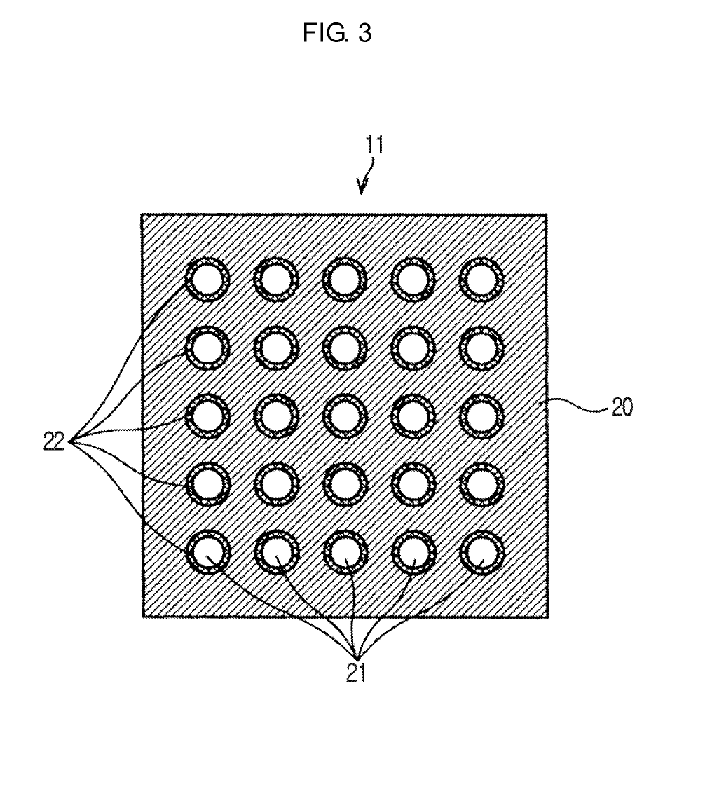

As shown in FIGS. 2 and 3, the probe supporting plate 11 includes a plurality of thin metal plates 20, for example, quadrangular thin metal plates. The plurality of thin metal plates 20 are laminated and bonded. A plurality of through-holes 21, into which the probes 10 are to be inserted, are formed in each of the thin metal plates 20. The through-holes 21 are connected to one another in a thickness direction of the plurality of thin metal plates 20, and the connected through-holes 21 pass through the plurality of thin metal plates 20 in the thickness direction. An insulating film 22 is formed on each of inner surfaces of the connected through-holes 21 and the surfaces of the probe supporting plate 11. The insulating film 22 is formed so that inner diameters of the through-holes 21 whereupon the insulating film 22 is formed match with diameters of the probes 10. Accordingly, when the probes 10 are inserted into the through-holes 21, the probes 10 may contact the insulating film 22 but do not directly contact the thin metal plates 20. Also, the thin metal plates 20 are formed of a material allowing diffusion bonding which will be explained later, for example, a stainless steel, a FeNi alloy, or the like. Also, the insulating film 22 is formed of a material having insulation, predetermined strength, adhesion, and chemical resistance, for example, polyimide, fluoride resin, or the like.

As shown in FIG. 1, the holding stage 3 is configured to freely move horizontally and vertically, so that the wafer W placed on the holding stage 3 may be moved in a three-dimensional manner to bring the probes 10 of the probe card 2 into contact with desired positions on the wafer W.

When electrical characteristics of an electronic circuit of the wafer W are inspected using the probe device 1 configured as described above, the wafer W is placed on the holding stage 3, and is raised toward the probe supporting plate 11 by the holding stage 3. Then, the electrodes of the wafer W are respectively brought into contact with the probes 10 corresponding to the electrodes, and electrical signals are transmitted and received between the printed wiring board 12 and the wafer W through the probe supporting plate 11. Accordingly, the electrical characteristics of the electronic circuit of the wafer W are inspected.

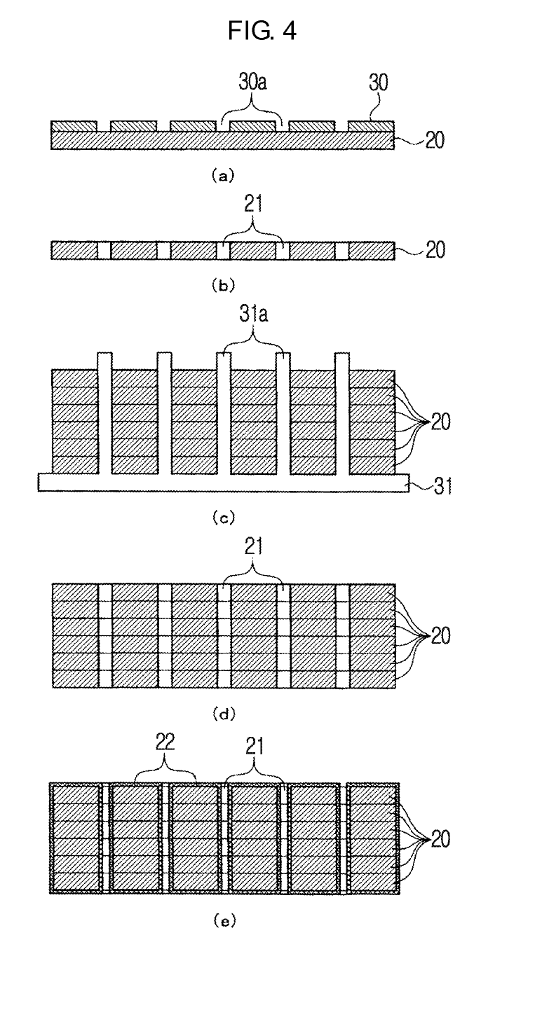

Next, a method for manufacturing the probe supporting plate 11 according to an embodiment of the present invention will be explained. FIG. 4 shows each of the processes for manufacturing the probe supporting plate 11.

First, as shown in FIG. 4(a), photolithography is performed on a thin metal plate 20, and a prescribed pattern 30 is formed on the thin metal plate 20. The pattern 30 is formed so that positions of recess portions 30a correspond to positions of the probes 10 to be inserted into the thin metal plate 20. Also, the pattern 30 is formed so that inner diameters of the recess portions 30a are greater than the diameters of the probes 10.

Next, the thin metal plate 20 is etched using the pattern 30 as a mask. Then, the pattern 30 is removed, and as shown in FIG. 4(b), the plurality of through-holes 21 having inner diameters greater than the diameters of the probes 10 are formed in the thin metal plate 20. The photolithography and the etching are performed on a plurality of the thin metal plates 20, and thus the plurality of through-holes 21 are formed at predetermined positions in each of the thin metal plates 20.

Here, a guide 31 shown in FIG. 4(c) is formed by the aforesaid photolithography. In the formation of the guide 31, exposure is performed by using the same exposure pattern as an exposure pattern used to form the pattern 30, and development is performed by inverting negative portions and positive portions. Accordingly, guide pins 31a are formed to protrude from the guide 31, at positions corresponding to the plurality of through-holes 21 of the thin metal plates 20. Also, the guide pins 31a are formed to have a length greater than a total thickness of the plurality of thin metal plates 20 that are laminated.

Then, as shown in FIG. 4(c), the plurality of thin metal plates 20 are laminated by conforming the through-holes 21 of the thin metal plates 20 to the guide pins 31a of the guide 31.

When the plurality of thin metal plates 20 are laminated, the guide 31 is removed, and as shown in FIG. 4(d), the plurality of thin metal plates 20 are bonded by diffusion bonding. In the diffusion bonding, the plurality of thin metal plates 20 are bonded by pressing and heating the plurality of laminated thin metal plates 20 in a controlled atmosphere, such as a vacuum atmosphere, an inert gas atmosphere, or the like.

When the plurality of thin metal plates 20 are bonded, the insulating film 22 is formed on surfaces of the thin metal plates 20 and inner surfaces of the through-holes 21, as shown in FIG. 4(e). The insulating film 22 is formed by adjusting a film thickness of the insulating film 22 so that the inner diameters of the through-holes 21 whereupon the insulating film is formed match with the diameters of the probes 10. Also, the insulating film 22 may be formed, for example, by electrodepositing an insulating material, or immersing the plurality of thin metal plates 20 in an insulating material.

Also, the manufacture of the probe supporting plate 11 is performed by a control unit (not shown). The control unit includes a program storing unit (not shown) that is, for example, a computer. The program storing unit stores a program which controls the manufacture of the probe supporting plate 11. Also, the program, which is recorded on a computer-readable storage medium such as a hard disk, a compact disk, a magneto-optical disk, a memory card, or the like, may be installed in the control unit from the storage medium.

According to the above embodiment, since the plurality of through-holes 21 into which the probes 10 are to be inserted are formed by etching the thin metal plates 20, the plurality of through-holes 21 may be simultaneously formed in one thin metal plate 20 through one etching process. Then, after the etching is performed on the plurality of thin metal plates 20, the plurality of thin metal plates 20 are bonded by laminating the plurality of thin metal plates 20 so that the through-holes 21 of the plurality of thin metal plates 20 are connected to one another in the thickness direction of the thin metal plates 20. Therefore the plurality of through-holes 21 into which the probes 10 are to be inserted may be formed in the probe supporting plate 11 only by performing etching a number of times corresponding to the number of thin metal plates 20 and bonding the thin metal plates 20. Accordingly, since there is no need to form all of through-holes through mechanical machining as in a conventional method, the probe supporting plate 11 may be manufactured in an extremely short time. Also, since the number of manufacturing processes is reduced, the probe supporting plate 11 may be manufactured at low costs.

Also, since the insulating film 22 is formed on each of the through-holes 21 of each of the thin metal plates 20, the thin metal plates 20 and the probes 10 are insulated from each other. Accordingly, when electrical characteristics of the wafer W are inspected, the thin metal plates 20 do not affect electrical signals of the probes 10.

Also, since the plurality of through-holes 21 of each of the thin metal plates 20 are formed by etching each of the thin metal plates 20, the fine through-holes 21 may be formed with high precision. Also, since the guide 31 is previously formed and the plurality of thin metal plates 20 are laminated by conforming each of the through-holes 21 to the guide pins 31a, the plurality of through-holes 21 may be connected to one another with high precision.

Also, since the inner diameters of the through-holes 21 whereupon the insulating film 22 is formed may be made to match with the diameters of the probes 10 by adjusting the thickness of the insulating film 22 formed on the through-holes 21, the probes 10 may be inserted into appropriate positions of the probe supporting plate 11.

Also, since the plurality of thin metal plates 20 are bonded by diffusion bonding, the thin metal plates 20 are surface-bonded, bonded surfaces can be maintained with high strength.

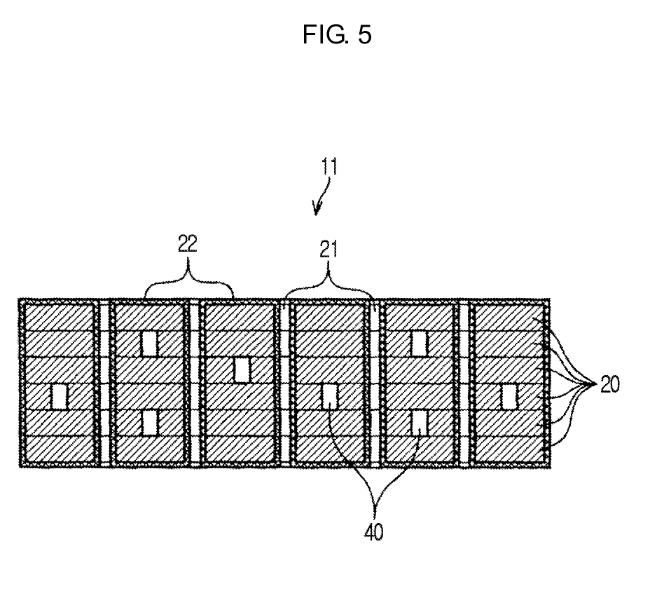

In the probe supporting plate 11 of the above embodiment, holes 40 other than the through-holes 21 may be arbitrarily formed in the thin metal plates 20, as shown in FIG. 5. In the formation of the holes 40, first, a pattern having recess portions at positions where the holes 40 are to be formed, in addition to the recess portions 30a for forming the through-holes 21 is formed on the thin metal plates 20, when the photolithography is performed on the thin metal plates 20. Then, the thin metal plates 20 are etched by using the pattern as a mask. Accordingly, the plurality of through-holes 21 and the holes 40 are simultaneously formed in the thin metal plates 20.

In this case, parts, sensors, and the like may be mounted in the holes 40 formed in the probe supporting plate 11. Various parts or sensors, for example, parts such as modules diagnosing electronic parts mounted on the wafer W as modules, itself, or the like, sensors such as a temperature sensor for detecting the temperature of the probe supporting plate 11, a pressure sensor for detecting a pressure applied to the probe supporting plate 11, or the like, and the like, may be mounted. Also, a path from the outside of the probe supporting plate 11 to the inside of the probe supporting plate 11 may be formed by connecting the holes 40. Accordingly, the aforesaid parts, sensors, and the like may be directly manipulated from the outside, or the probe supporting plate 11 may be cooled by flowing air or cooling water through the flow path. Also, the weight of the probe supporting plate 11 itself may be reduced by forming the holes 40, thereby making it easy to handle the probe supporting plate 11.

Although the plurality of through-holes 21 are formed by respectively etching the plurality of thin metal plates, and then the thin metal plates 20 are laminated and bonded in the above embodiments, a plurality of through-holes may be formed in one metal plate by etching the one metal plate. For example, the one metal plate is a metal plate having the same thickness as a total thickness of the plurality of thin metal plates 20 that are laminated. In this case, a plurality of desired through-holes are formed in the metal plate through one etching process, and an insulating film may be formed on surfaces of the metal plate and inner surfaces of the through-holes. Accordingly, the probe supporting plate 11 may be manufactured in a shorter time and at lower costs.

In the probe supporting plate 11 of the above embodiments, the through-hole 21 of one thin metal plate 20 may be formed to have a diameter different from a diameter of the through-hole 21 of another thin metal plate 20.

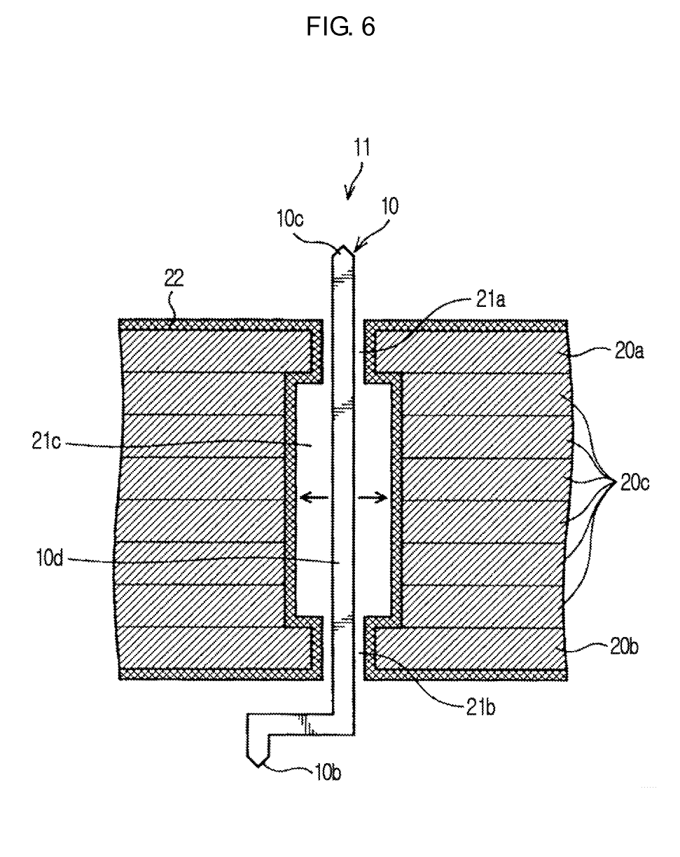

For example, as shown in FIG. 6, it is possible that diameters of through-holes 21c formed in thin metal plates 20c that are intermediate layers laminated between a thin metal plate 20a, which is an uppermost layer, and a thin metal plate 20b, which is a lowermost layer, are greater than diameters of through-holes 21a and 21b respectively formed in the thin metal plate 20a, which is the uppermost layer, and the thin metal plate 20b, which is the lowermost layer. The diameters of the through-hole 21a and the through-hole 21b are the same. When the pattern 30 is first formed on each of the thin metal plates 20 as shown in FIG. 4, the through-holes 21a, 21b, and 21c are formed by adjusting the inner diameters of the recess portions 30a of the pattern 30. In this case, even when a horizontal force is applied to the probes 10, main body portions 10d of the probes 10, which extend in a vertical direction can move in a horizontal direction (direction indicated by arrow of FIG. 6) in the through-holes 21c. Accordingly, the degree of freedom for deformation of the probes 10 inserted into the probe supporting plate 11 can be increased.

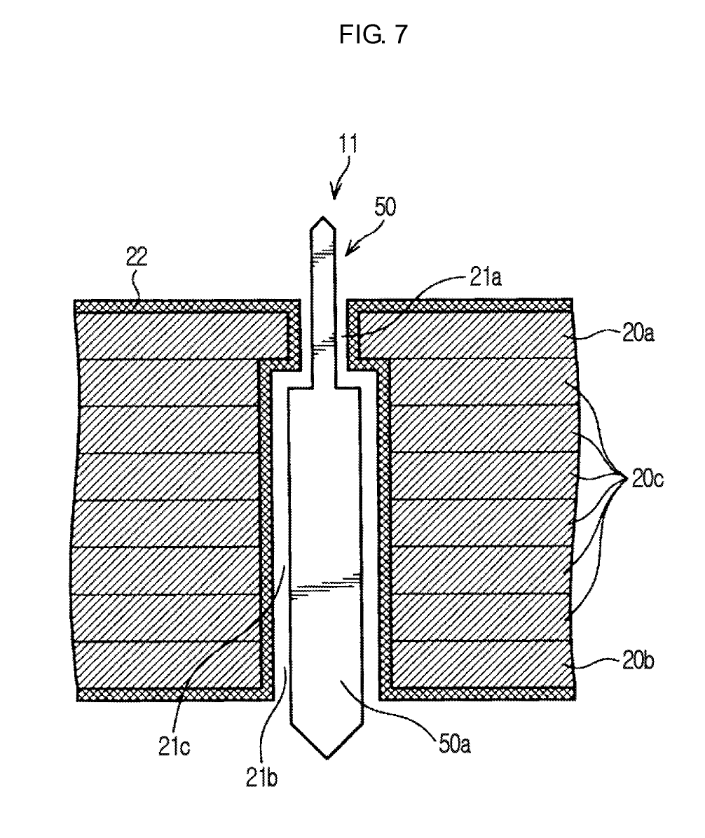

Also, for example, as shown in FIG. 7, if diameters of main body portions 50a of probes 50 which extend in the vertical direction are changed in the vertical direction, the diameters of the through-holes 21 may be changed to conform to the shapes of the main body portions 50a. In the present embodiment, each of the main body portions 50a may have an upper diameter that is less than a lower diameter. Then, in order to match with the shape of the main body portion 50a, the diameter of the through-hole 21a of the thin metal plate 20a that is the uppermost layer is less than each of the diameters of the through-holes 21b and 21c of the thin metal plates 20b and 20c disposed under the thin metal plate 20a. Since the diameters of the through-holes 21 formed in the probe supporting plate 11 may be changed easily as described above, the degree of freedom of the shapes of the probes 50 inserted into the probe supporting plate 11 may be increased.

While very appropriate embodiments of the present invention has been described by referring to the attached drawings, the present invention is not limited to the embodiments. It will be clearly understood by those of ordinary skill in the art that various modifications or changes may be made therein within the spirit and scope of the present invention as defined by the following claims and also belong to the spirit and scope of the present invention. The present invention is not limited to the embodiments and may adopt various other types.

### INDUSTRIAL APPLICABILITY

The present invention may be used for a probe supporting plate which holds a plurality of probes for inspecting electrical characteristics of an object to be inspected and a method for manufacturing the probe supporting plate.

1. A method for manufacturing a probe supporting plate which holds a plurality of probes for inspecting electrical characteristics of an object to be inspected, the method comprising:
an etching process of etching a metal plate to form a plurality of through-holes, into which the probes are to be inserted, in the metal plate; and
a film forming process of forming an insulating film on each of inner surfaces of the through-holes.

2. The method of claim 1, wherein:
in the etching process, each of the through-holes is formed to have a diameter greater than each of diameters of the probes, and
in the film forming process, a thickness of the insulating film is adjusted so that inner diameters of the through-holes whereupon the insulating film is formed match with the diameters of the probes.

3. The method of claim 1, wherein:
the metal plate comprises a plurality of thin metal plates,
in the etching process, each of the plurality of thin metal plates is etched to form a plurality of through-holes, into which the probes are to be inserted, in each of the thin metal thin plates, and
after the etching process and before the film forming process, there is performed a bonding process of bonding the plurality of thin metal plates by laminating the plurality of thin metal plates so that the through-holes of the plurality of thin metal plates are connected to one another in a thickness direction of the thin metal plates.

4. The method of claim 3, wherein in the etching process, holes other than the through-holes are further formed in the thin metal plates.

5. The method of claim 3, wherein in the bonding process, the bonding of the plurality of thin metal plates is performed by diffusion bonding.

6. The method of claim 3, wherein in the etching process, the through-hole of one thin metal plate is formed to have a diameter different from a diameter of the through-hole of another thin metal plate.

7. The method of claim 6, wherein in the etching process, the through-hole of the thin metal plate that is an intermediate layer laminated between an uppermost layer and an lowermost layer is formed to have a diameter greater than each of diameters of the through-holes of the thin metal plates that are respectively the uppermost layer and the lowermost layer.

8. A computer-readable storage medium which stores a program operating in a computer of a control unit which controls a manufacturing device in order to execute a method for manufacturing a probe supporting plate by using the manufacturing device,
wherein the method for manufacturing a probe supporting plate comprises:
an etching process of etching a metal plate to form a plurality of through-holes, into which probes are to be inserted, in the metal plate; and
a film forming process of forming an insulating film on each of inner surfaces of the through-holes.

9. A probe supporting plate which holds a plurality of probes for inspecting electrical characteristics of an object to be inspected, the probe supporting plate comprising:
a metal plate in which a plurality of through-holes into which the probes are to be inserted are formed,
wherein an insulating film is formed in each of inner surfaces of the through-holes.

10. The probe supporting plate of claim 9, wherein:
the metal plate is formed by laminating and bonding a plurality of thin metal plates.
a plurality of through-holes are formed in each of the thin metal plates, and
the plurality of through-holes of each of the thin metal plates are connected to one another in a thickness direction of the thin metal plates.

11. The probe supporting plate of claim 10, wherein holes other than the through-holes are further formed in the thin metal plates.

12. The probe supporting plate of claim 10, wherein a diameter of the through-hole of one thin metal plate is different from a diameter of the through-hole formed in another thin metal plate.

13. The probe supporting plate of claim 12, wherein a diameter of the through-hole formed in the thin metal plate that is an intermediate layer laminated between an uppermost layer and a lowermost layer is greater than each of diameters of the through-holes formed in the thin metal plates that are respectively the uppermost layer and the lowermost layer.
